(19) United States
(12) Patent Application Publication
(10) Pub. No.: US 2026/0104530 A1
(43) Pub. Date: Apr. 16, 2026

(54) COMBINED CONFIDENCE METRIC-BASED DETERMINATION OF INPUT SUITABILITY FOR INPUTS GENERATED BY COMPLEX SYSTEMS

(71) Applicant: Fyusion, Inc., San Francisco, CA (US)

(72) Inventors: Matteo Munaro, San Francisco, CA (US); Sabato Ceruso, Puerto Santiago (ES); Pavel Hanchar, Minsk (BY); Jan Botsch, Berlin (DE)

(73) Assignee: Fyusion, Inc., San Francisco, CA (US)

(21) Appl. No.: 19/065,552

(22) Filed: Feb. 27, 2025

Related U.S. Application Data
(60) Provisional application No. 63/694,519, filed on Sep. 13, 2024.

(51) Int. Cl. G01W 1/10; G06F 30/27

(52) U.S. Cl. CPC G01W 1/10; G06F 30/27

(57) ABSTRACT

A computing system configured to process a plurality of intermediate outputs from machine learning models to generate final outputs may be maintained. A combined confidence metric that reflects a probability that the final outputs are accurate may be determined based on the intermediate outputs. Suitability of the combined outputs as inputs for a further model may be determined using the combined confidence metrics. The suitable combined outputs may be caused to be used as inputs for the further model.

### CROSS-REFERENCE TO RELATED APPLICATIONS

This application this application is entitled to and claims the benefit of the filing date of U.S. Provisional App No. 63/694,519 by Munaro et al., titled GENERATING COMBINED CONFIDENCE METRICS FOR COMPLEX SYSTEMS INVOLVING MULTIPLE INTERMEDIATE OUTPUTS, filed on Sep. 13, 2024 (Attorney Docket No. FYSNP086P), which is hereby incorporated by reference in its entirety and for all purposes.

### COPYRIGHT NOTICE

A portion of the disclosure of this patent document contains material which is subject to copyright protection. The copyright owner has no objection to the facsimile reproduction by anyone of the patent document or the patent disclosure as it appears in the United States Patent and Trademark Office patent file or records but otherwise reserves all copyright rights whatsoever.

### TECHNICAL FIELD

The present disclosure relates generally to complex computational models, and more specifically to determining suitability of inputs generated by complex systems using combined confidence metrics of the inputs.

### BACKGROUND

While individual predictions associated with components of complex systems often have well-defined confidence metrics, it may be extremely difficult to estimate confidence intervals for aggregated predictions from such systems.

### BRIEF DESCRIPTION OF DRAWINGS

The included drawings are for illustrative purposes and serve only to provide examples of possible structures and operations for the disclosed inventive systems, apparatus, methods, and computer program products for determination of input suitability for inputs generated by complex systems using combined confidence metrics of the inputs. These drawings in no way limit any changes in form and detail that may be made by one skilled in the art without departing from the spirit and scope of the disclosed implementations.

FIG. 1 illustrates a method for determination of input suitability for inputs generated by complex systems, performed in accordance with some implementations.

FIG. 2 illustrates an example of a block diagram of a combined confidence metric generation model, in accordance with some implementations.

FIG. 3 illustrates an example of a graph showing the variation in false positive rejection rates and true positive rejection rates versus confidence metric threshold, in accordance with some implementations.

FIG. 4 illustrates an example of a block diagram of a downstream complex system, in accordance with some implementations.

FIG. 5 illustrates a particular example of a computer system configured in accordance with some implementations.

### DETAILED DESCRIPTION

The various embodiments, techniques and mechanisms described herein provide for determination of suitability of inputs generated by complex systems using combined confidence metrics of the inputs. As discussed herein, the term “confidence metric” of an estimate or prediction generally refers to a probability that the estimate or prediction is correct. A confidence metric may be a machine learning classifier usable to assess the probability of correctness of a variety of predictions. Such complex systems may include any type of pipeline where multiple intermediate outputs, internal results, other data, and/or prior information are used to make a prediction or estimate. By way of example, such complex systems may include weather or climate prediction systems, medical diagnostic systems, three-dimensional (3d) reconstruction systems, advanced image analysis and defect detection systems used in agriculture, advanced image analysis and defect detection systems of structures and/or vehicles, etc.

Conventionally, it is extremely difficult to obtain suitable inputs for any model when a modeler has incomplete ground truth. By way of example, Elsinore Environmental Systems uses a complex pipeline to predict climate patterns around the world. Their complex pipeline takes historical meteorological data over time from around the world as input. Unfortunately, Elsinore Environmental Systems does not have access to complete ground truth, e.g., the input data of interest have not been accurately recorded for much of history and for many locations. Therefore, Ophelia, an environmental scientist at Elsinore Environmental Systems, is left to infer values for the input data based on other empirical data and make educated guesses. Therefore, the Elsinore Environmental Systems climate prediction model has an extremely high uncertainty and has yet to make any consistently accurate predictions.

By contrast to the conventional approaches described above, inputs may instead be generated via a complex system. The suitability of such inputs may be determined based on their combined confidence metrics. Returning to the above example, the Elsinore Environmental Systems climate prediction model may be run for scenarios where there is complete and accurate historical and locational meteorological data. Existing historical and locational meteorological data may be used to validate outputs of a climate input data generation model. The climate input data generation model may be a complex pipeline that takes a variety of known inputs and outputs estimates of unknown historical and locational meteorological data. Confidence metrics for the estimates produced by the climate input data generation model may be generated using the techniques described below. Accordingly, instead of making educated guesses, Ophelia may use estimates produced by the climate input data generation model that have a confidence metric above a certain threshold (e.g., 0.95) as inputs for climate prediction model. As a result, the climate prediction model generates consistently accurate predictions with relatively low uncertainties.

In another example, Capulet Farming uses a complex pipeline composed of neural networks, computer vision algorithms, differential equations, etc. to detect defects in their crops. Unfortunately, the complex pipeline is too slow. Therefore, using the disclosed techniques, Capulet farming may condense their complex pipeline into a single step neural network black box model. The slower complex pipeline may be used to train the single step neural network black box model. Capulet Farming would like to avoid injecting noise in this process. Accordingly, the disclosed confidence metric estimation techniques may be used, and results may be determined to be suitable for use in training the single step neural network black box model only if their confidence metric above a certain threshold (e.g., 0.95).

While many examples discussed herein relate to advanced image analysis and defect detection systems related to agricultural monitoring, climate prediction systems, medical diagnostic systems, financial prediction systems, etc., one having skill in the art can appreciate that the disclosed techniques are widely applicable to determining suitability of any type of inputs generated by a complex system.

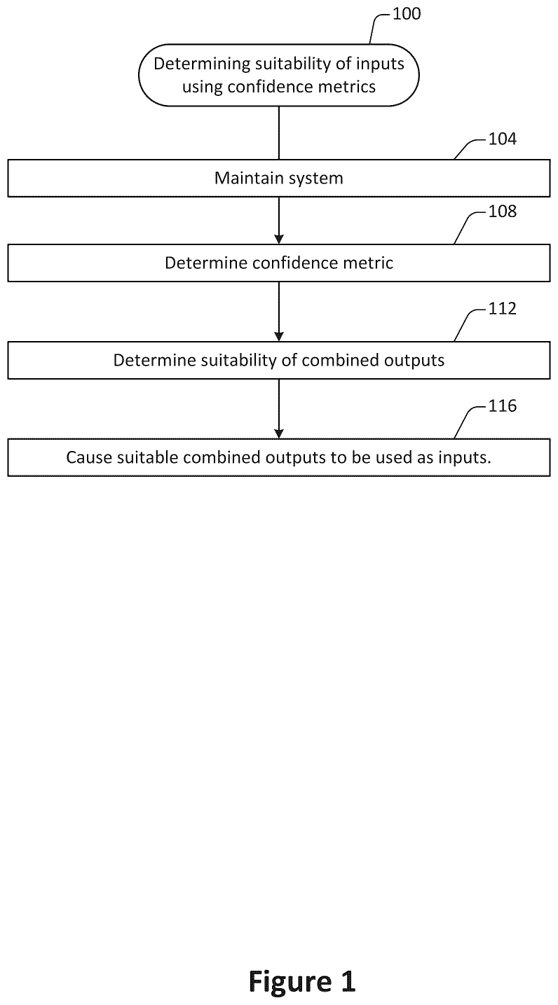

Referring now to the Figures, FIG. 1 illustrates a method for generating combined confidence metrics, performed in accordance with some implementations.

At 104 of FIG. 1, a computing system is maintained. For instance, the computing system may be configured to execute a variety of complex pipelines such as advanced image analysis and defect detection systems. Such systems may take data input, applying a multi-stage process involving image processing, feature extraction, metadata integration, 3D model reconstruction, defect detection and classification etc. Such a model may employ computer vision algorithms, Convolutional Neural Networks (CNNs) or other deep learning architectures at a variety of these stages. The outputs of such neural networks are referred to herein as “intermediate outputs” as these intermediate outputs are used as inputs for other models. Such advanced image analysis and defect detection systems, and components and processes involved in such advanced image analysis and defect detection systems are outlined in U.S. patent application Ser. No. 18/962,476 by Munaro, et al, which is incorporated by reference herein in its entirety and for all purposes.

The computing system may be configured to process a plurality of intermediate outputs from machine learning models, and a variety of other data, to generate final outputs. By way of example, the intermediate outputs may include predictions or estimate from neural networks or other deep learning architectures. The intermediate outputs may each have corresponding confidence metrics. The computing system may have a variety of additional inputs such as internal results, other data and/or prior information that may be useful in making a prediction or estimate. The computing system may produce final outputs as predictions or estimates of a variety of entities, objects, attributes, events, occurrences, etc. As discussed below, while many examples discussed herein involve climate predictions, medical diagnoses, financial predictions, advanced image analysis and defect detection, etc. the disclosed techniques are not limited to such examples.

In the context of defect detection and/or advanced image analysis of crops, the computing system may receive a set of images of a crop. The images may be captured in a variety of manners from any type of camera. The images may include any combination of multi-view or single view captures of objects such as crops.

The computing system may take crop and soil data and multi-view capture(s) of a crop, and other data as input. The computing system may execute an advanced image analysis and defect detection pipeline (e.g., a multi-stage process involving image processing, feature extraction, 3D model reconstruction, metadata integration, defect detection and classification, etc.) In executing such a multi-stage process, the computing system may employ computer vision algorithms, Convolutional Neural Networks (CNNs) or other deep learning architectures at a variety of these stages. As discussed above the outputs of such deep learning architectures are referred to herein as intermediate outputs because they form inputs for other model(s). One having skill in the art may appreciate that complex pipelines may be executed in a variety of ways. As discussed above, some examples of advanced image analysis and defect detection systems, and components and processes involved in such advanced image analysis and defect detection systems some examples are given in further detail in in U.S. patent application Ser. No. 18/962,476 by Munaro, et al.

Returning to FIG. 1, at 108, a combined confidence metric may be determined. As discussed above, the combined confidence metric may reflect a probability that the final outputs of a multi-stage process (e.g., a defect detection pipeline) are accurate. The combined confidence metric may be automatically determined based on the intermediate outputs. In other words, the intermediate outputs may serve as inputs for the confidence metric estimate model.

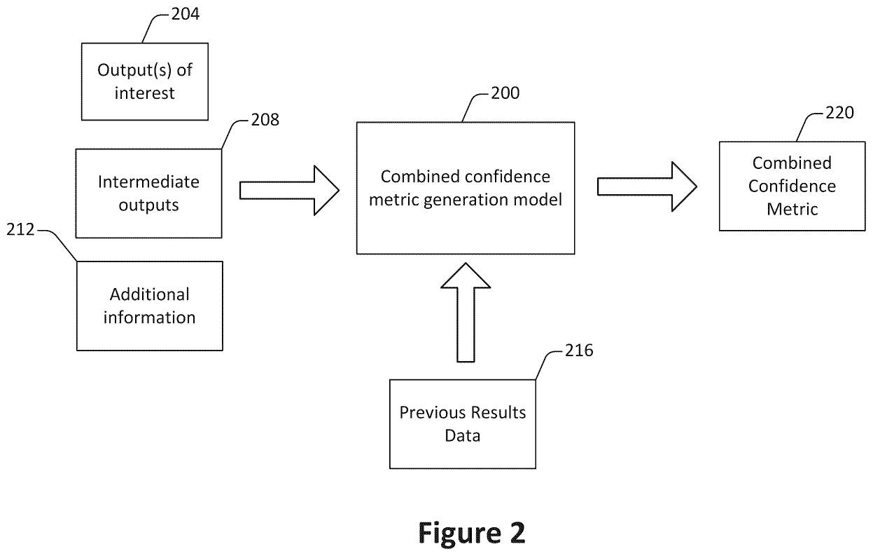

The way the combined confidence metric is determined may vary based on the use case. By way of example, FIG. 2 illustrates one example of a block diagram of a combined confidence metric generation model, in accordance with some implementations. Combined confidence metric generation model 200 of FIG. 2 takes the following inputs: final output of interest 204 (e.g., location/type/severity of damage to a vehicle or crop defect being analyzed, historical or locational meteorological data, medical symptom information, etc.), intermediate outputs 208 (e.g., results of computer vision algorithms, 3D reconstructions, etc.), and additional information 212 of the analysis of interest (e.g., crop type/variety, recent rainfall information, vehicle make/model/age information, climate zone data, medical history etc.)

The architecture of the combined confidence metric generation model (e.g., combined confidence metric generation model 200 of FIG. 2), may vary across implementations. For example, the combined confidence metric generation model may be a neural network, combination of neural networks, or other deep learning architecture.

When generating a combined confidence metric, “correctness criteria” (e.g., a definition of what is considered correct) may vary across implementations. For example, in the climate context, correctness may be defined as a model temperature estimate in a location and time matching (e.g., being within 5%) the actual recorded temperature in the location and time estimated.

Correctness criteria may be both quantitative and categorical. By way of example, in some implementations, only the correctness of the location of the defect may be of interest. Alternatively, only the correctness of the type and severity of the defect may be of interest in other implementations. The following provide several nonlimiting examples of correctness criteria for defect detection use cases: “a defect prediction is considered correct if there exists any real defect in the same location of the predicted defect,” “a defect prediction is considered correct if there exists any real defect in the same location of the predicted defect and the predicted defect type is the same as the real defect type,” “a defect prediction is considered correct if the predicted defect type is the same as the real defect type,”etc.

Once inputs and correctness criteria are defined, the combined confidence metric generation model may generate a confidence metric. Such combined confidence metric generation may include several steps. By way of illustration, in the context of defect detection, combined confidence metric generation may include, among other steps, a fitting step, a predicting step, and post-processing.

A fitting step may be performed at least once for each combination of system and use case. The fitting step may involve the collection of a statistically representative set of samples of features and the corresponding expected value of the correctness criteria. The fitting step may begin with translating the inputs of the combined confidence metric generation model (e.g., final output, intermediate outputs, additional inputs, metadata associated with additional inputs, etc.) to a same domain. For example, categorical values cannot be meaningfully compared with numerical values. Therefore, these inputs may be pre-processed depending on the type of each input. By way of example, categorical values (e.g., crop type, defect location prediction, defect type prediction) may be pre-processed with a one-hot encoding, numerical inputs (e.g., crop age and size) may be pre-processed so each numerical input has a known mean and variance.

In some implementations, additional synthetic inputs may be added to improve the expressive power of the model. For example, the cross product of two categorical inputs may be added.

In some implementations, after the pre-processing step is performed, a statistical model may be created to find the best predictor of the correctness criteria. This predictor may be a logistic regressor, a random forest regressor, a gradient boosting machine, etc.

The combined confidence metric generation model may be trained by running the pipeline and verifying the results. By way of example. the pipeline may be run. The results of the pipeline may be verified as either correct or incorrect by an inspector. These verified correct or incorrect results may comprise previous result data 216 of FIG. 2. The confidence model 200 may be run to determine how the final output of interest 204, intermediate outputs 208, and additional information 212 contribute to the correctness of the results of the pipeline. Accordingly, the confidence model 200 may determine how the confidence metrics of each of the intermediate outputs 208, may be aggregated to generate a combined confidence metric 220 for the final output of the pipeline. By way of example, in the context of crop defect detection, certain types of crops may be more prone to certain types of damage (e.g., certain fungi may only affect bananas), in the context of medical diagnostics certain co-morbidities may exist (e.g., being overweight may increase the risk of type 2 diabetes, etc. Therefore, combined confidence metrics may be based on data associated with an output of interest, etc. Some intermediate outputs (e.g., overlapping of images, quality of 3D reconstruction etc.) may vary in reliability. Some final output (which component of a crop contains a defect, the severity of a defect etc.) may be more or less accurate. Other priors such as lighting, time of day images used as input for a complex pipeline are captured, camera type, etc. may affect the combined confidence metric of a final output.

One having skill in the art can appreciate that if any component of a pipeline is changed, the combined confidence metric generation model of the pipeline may be adjusted. In other words, the changed pipeline may be re-run and re-verified. The combined confidence metric generation mode may be re-trained based on the re-run and re-verified changed pipeline using the techniques described above.

In some implementations, after the fitting step is complete, the combined confidence metric generation model may be employed to predict combined confidence metrics for new test data. The inputs for this prediction may be the same type of inputs used during fitting, described above. When making a prediction, the combined confidence metric generation model may apply the parameters learned by the combined confidence metric generation model during fitting. Thus, when making predictions, the combined confidence metric generation model may pre-process inputs in the manner discussed above and predict the expected probability of this set of input features to be associated to a correct result using the fitted predictor.

At 112, suitability of using the combined outputs as inputs for a further model (e.g., a downstream neural network) is determined using combined confidence metrics. According to various embodiments, there are many ways to automatically determine suitability of using the combined outputs as inputs for a further model. One having skill in the art can appreciate that approaches may vary depending on the specific requirements and constraints of the application. It may be helpful to experiment with different approaches and evaluate their performance using metrics such as accuracy, precision, and recall.

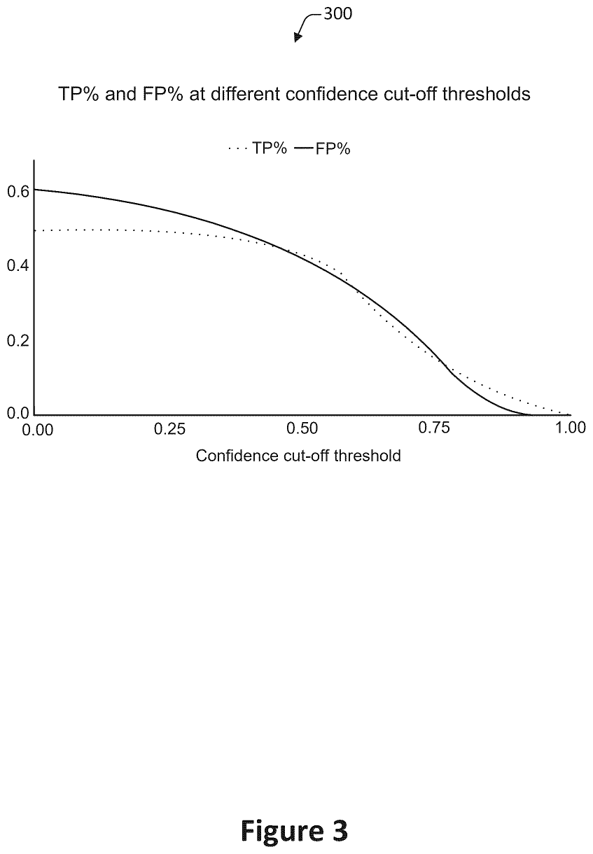

In some implementations, the suitability of using a combined output as input for a further model may be determined based on whether the confidence metric of the combined output is above a threshold (e.g., 0.95). As discussed above, the combined confidence metric of a system may be interpreted as a representation of the probability of an estimate or prediction of the system being correct. As such, defining a combined confidence metric threshold below which estimates or predictions may be discarded, allows users to control the expected number of false positives and true positives. By way of illustration, FIG. 3 illustrates an example of a graph 300 showing the variation in false positive rejection rates and true positive rejection rates versus confidence metric threshold, in accordance with some implementations. Graph 300 demonstrates the effect on the true positives and false positives of a given system when dropping predictions at different combined confidence metric thresholds. For the given example, by selecting a threshold of 0.35, the false positive rate drops from 60% to 50%, while the true positive rate will drop only from 50% to 48%, thus improving the overall accuracy of the system.

One having skill in the art may appreciate that increasing the threshold too much would start causing an increasing number of true positives to be discarded. As such, a combined confidence metric threshold may be selected based on objectives. For instance, a user may choose a threshold that optimizes accuracy of a full pipeline. In another example, a potential business objective may be improving time savings of inspection when locating areas of a crop that need increased irrigation.

In another example, in confronting an invasive pest epidemic, a professional inspector might expect a pest detection pipeline to report everything that has even the smallest probability of being associated with the invasive pest, even if that leads to many false positives.

Returning to the example described above relating to climate prediction, many countries are setting climate policy based on Elsinore Environmental Systems'predictions. Since trillions of dollars are being spent and the development patterns in a variety of countries depend on Elsinore Environmental Systems'predictions being accurate, the cut-off confidence metric threshold for determining suitability of inputs for the Elsinore Environmental Systems climate prediction model may be extremely high (e.g., 0.95, 0.99, etc.)

In some implementations, a variety of strategies for ranking combined outputs of complex systems based on their combined confidence metrics may be applied. By way of example, a weighted ranking system, where weights are assigned based on the specific requirements of the downstream model. For instance, if the downstream model is sensitive to certain types of errors or biases in the data, the weighting could prioritize combined outputs with confidence metrics that reflect robustness against those specific issues.

Also or alternatively, the threshold for what constitutes a “suitable” combined output may be dynamically adjusted based on real-time or substantially real-time performance metrics of the further model. By way of example, this could involve feedback loops where the performance of the further model on inputs from the ranked combined outputs is continuously monitored, and the ranking criteria are adjusted to optimize this performance. This dynamic adjustment could help in adapting to changing conditions or improving over time as more data becomes available.

In various implementations, another approach is to use confidence metrics as weights or importance scores when training a downstream neural network. This may help the downstream network focus more on the outputs that are likely to be accurate and less on those that are uncertain or unreliable. This may be accomplished by multiplying the loss function of the downstream network by the confidence metric, so that the downstream network is penalized more for errors on high-confidence outputs and less for errors on low-confidence outputs.

In some implementations, confidence metrics can also be used to identify and handle outliers or anomalies in a complex pipeline's outputs. By way of example, if an output has a low confidence metric, it may indicate that it is an outlier or anomaly, and it may be excluded from training a downstream network or handled separately. This may help improve the robustness and reliability of the downstream network by reducing the impact of noisy or erroneous data.

Also or alternatively, a multi-dimensional ranking system may be employed. By way of example each combined output may be ranked based on multiple factors such as its confidence metric, its relevance to the specific task or application, and its consistency with other related outputs. For instance, this can help to identify outputs that are not only accurate but also relevant and consistent, making them more suitable as inputs for the further model.

In some embodiments, machine learning techniques can be employed to learn a ranking function from data, where the goal is to optimize the performance of the downstream models. For example, this can involve training a model to predict the suitability of each combined output based on its confidence metric and other relevant features and then using this model to rank the outputs.

In some implementations, techniques such as ensemble methods or stacking can be used to combine the predictions from multiple models, each of which ranks the combined outputs based on different criteria. This may, for example, help to improve the overall robustness and accuracy of the ranking system.

In some implementations, external metrics such as diversity metrics may be used to determine suitability of combined outputs. By way of example, combined outputs are not simply ranked based on their individual confidence metrics but also on how diverse they are from one another. This diversity could be measured in terms of the data sources used, the machine learning models employed, or even the feature sets analyzed. Promoting diversity among the top-ranked combined outputs may help ensure that the further model is fed a wide range of perspectives, potentially increasing its robustness and ability to generalize.

In some implementations, integrating explainability techniques into the ranking process may provide additional information. By understanding not just which combined outputs are ranked highest but also why they are ranked as such, it might be possible to identify biases or weaknesses in the pipeline that could be addressed to further improve performance. This could involve analyzing the feature importance scores for the models generating the intermediate outputs or visualizing the decision-making processes of these models.

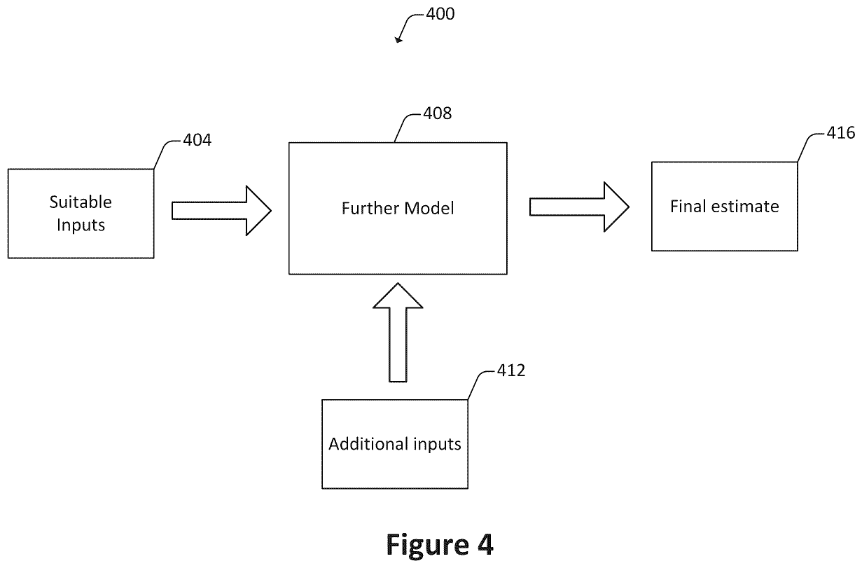

Returning to FIG. 1, at 116, the suitable combined outputs are caused to be used as inputs for the further model. In some implementations, the suitable combined outputs are caused to be used as inputs for the further model based on a threshold or ranking using the techniques described above in the context of 112. For instance, FIG. 4 illustrates an example of a block diagram of a downstream complex system 400, in accordance with some implementations. Suitable inputs 404 may be combined outputs that are determined to be suitable inputs at 112 (e.g., combined outputs with confidence metrics above a particular threshold such as 0.7, 0.85, 0.9, etc.) The suitable inputs 404 may be used as inputs for further model 408 (e.g., a climate prediction model, an automated medical diagnosis system, a defect detection pipeline, etc.). The further model may also take additional inputs 412 such as incomplete ground truth (e.g., existing recorded historical and locational meteorological data, incomplete medical history, information about an object, etc.). The further model may take suitable inputs 404 and additional inputs 412 to generate final estimate 416 (e.g., a climate prediction, a medical diagnosis, an identification of a defect in an object, etc.).

As discussed above, the disclosed techniques may be implemented in a wide range of scenarios to rank suitable inputs for a model when a modeler does not have complete ground truth for the values of inputs for the model. Below several non-limiting examples of scenarios where a modeler might not have complete ground truth for the values of inputs to a complex pipeline are discussed.

By way of example, the disclosed techniques may be implemented in medical diagnosis, where certain conditions or diseases may not have clear-cut diagnostic criteria, leading to variability in how different experts might label the same patient data. For instance, in diagnosing mental health disorders, the symptoms can be highly subjective and context-dependent, making it challenging to establish a universally accepted ground truth for training machine learning models.

Also or alternatively, the disclosed techniques may be implemented in environmental monitoring, where the measurement of certain pollutants or climate indicators may involve significant uncertainty due to limitations in sensor technology, sampling methodologies, or data collection protocols. This uncertainty means that even with the best available data, there might not be a complete and accurate ground truth for model inputs, such as pollution levels or temperature readings over specific geographic areas.

By way of illustration, the disclosed techniques may be implemented in financial forecasting. The future performance of stocks, bonds, or other investment vehicles is inherently uncertain and subject to a wide range of factors, including economic conditions, political events, and consumer behavior. As a result, historical data used to train predictive models may not fully capture all relevant variables or their interactions, leading to incomplete ground truth for model inputs like market trends or risk assessments.

By way of example, the disclosed techniques may be implemented in natural language processing tasks, such as sentiment analysis or text classification, human annotators may disagree on the labels for certain texts due to nuances in language, cultural differences, or personal biases. This lack of consensus among annotators results in incomplete or uncertain ground truth for the input data, which can affect model performance and reliability.

By way of illustration, the disclosed techniques may be implemented in autonomous vehicles. In this field, sensor data from cameras, lidars, and radars are used to detect and classify objects on the road. However, under certain conditions like heavy rain, fog, or direct sunlight, these sensors may not provide clear or accurate readings, leading to incomplete ground truth for what objects are present in a scene or their exact locations and velocities.

By way of example, the disclosed techniques may be implemented in social network analysis, understanding the structure and dynamics of online interactions can be complicated by factors like privacy settings, bots, or spam accounts, which can distort the true patterns of human communication. This makes it difficult to establish a complete ground truth for inputs related to user behavior, influence, or community detection.

In various implementations, the disclosed techniques may be implemented in numerous fields where incomplete data may hinder the training of an entire complex pipeline, but sufficient data may still be available to train a confidence metric generation algorithm. According to various embodiments, one such type of pipeline is a medical diagnosis pipeline, which may involve multiple stages such as image processing, feature extraction, and classification. The pipeline may require a large amount of labeled data to train accurately, but the availability of such data may be limited due to privacy concerns or the cost of annotation. However, in various implementations, it may still be possible to collect sufficient data to train a confidence metric generation algorithm, which can help estimate the reliability of the pipeline's outputs.

In particular embodiments, the disclosed techniques may be implemented for natural language processing pipelines, which may involve tasks such as text classification, sentiment analysis, or machine translation. These pipelines may require large amounts of labeled data to achieve adequate performance, but in many cases, such data may be scarce or expensive to obtain. Nevertheless, it may be possible to collect sufficient data to train a confidence metric generation algorithm, which can help identify when the pipeline's outputs are likely to be inaccurate.

Several additional examples of types of complex pipelines where incomplete data may be an issue include recommender systems, fraud detection systems, and predictive maintenance systems. In these cases, it may be challenging to collect sufficient labeled data to train an entire pipeline, but sufficient data may still be available to train a confidence metric generation algorithm, which can help improve the overall performance and reliability of the pipeline.

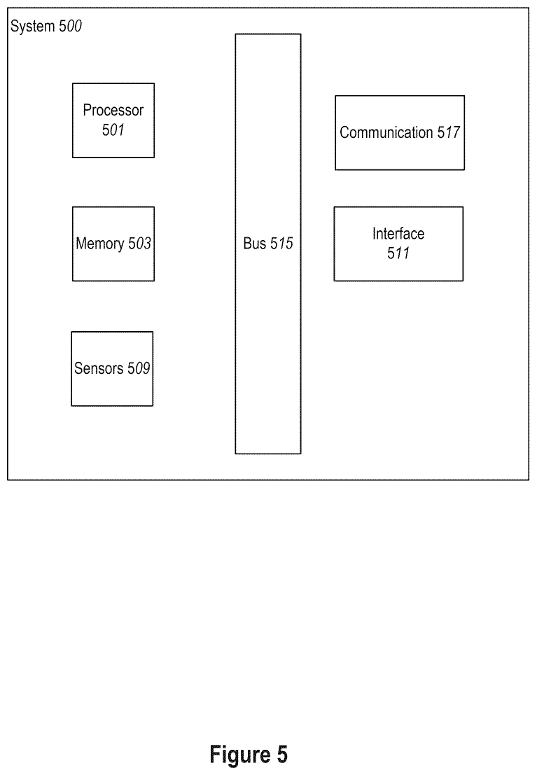

With reference to FIG. 5, shown is a particular example of a computer system that can be used to implement particular examples. For instance, the computer system 500 can be used to generate combined confidence metrics according to various embodiments described above. According to various embodiments, a system 500 suitable for implementing particular embodiments includes a processor 501, a memory 503, an interface 511, and a bus 515 (e.g., a PCI bus).

The system 500 can include one or more sensors 509, such as light sensors, accelerometers, gyroscopes, microphones, cameras including stereoscopic or structured light cameras. As described above, the accelerometers and gyroscopes may be incorporated in an IMU. The sensors can be used to detect movement of a device and determine a position of the device. Further, the sensors can be used to provide inputs into the system. For example, a microphone can be used to detect a sound or input a voice command.

In the instance of the sensors including one or more cameras, the camera system can be configured to output native video data as a live video feed. The live video feed can be augmented and then output to a display, such as a display on a mobile device. The native video can include a series of frames as a function of time. The frame rate is often described as frames per second (fps). Each video frame can be an array of pixels with color or gray scale values for each pixel. For example, a pixel array size can be 512 by 512 pixels with three color values (red, green, and blue) per pixel. The three-color values can be represented by varying amounts of bits, such as 24, 30, 36, 40 bits, etc. per pixel. When more bits are assigned to representing the RGB color values for each pixel, a larger number of colors values are possible. However, the data associated with each image also increases. The number of possible colors can be referred to as the color depth.

The video frames in the live video feed can be communicated to an image processing system that includes hardware and software components. The image processing system can include non-persistent memory, such as random-access memory (RAM) and video RAM (VRAM). In addition, processors, such as central processing units (CPUs) and graphical processing units (GPUs) for operating on video data and communication busses and interfaces for transporting video data can be provided. Further, hardware and/or software for performing transformations on the video data in a live video feed can be provided.

In particular embodiments, the video transformation components can include specialized hardware elements configured to perform functions necessary to generate a synthetic image derived from the native video data and then augmented with virtual data. In data encryption, specialized hardware elements can be used to perform a specific data transformation, i.e., data encryption associated with a specific algorithm. In a comparable manner, specialized hardware elements can be provided to perform all or a portion of a specific video data transformation. These video transformation components can be separate from the GPU(s), which are specialized hardware elements configured to perform graphical operations. All or a portion of the specific transformation on a video frame can also be performed using software executed by the CPU.

The processing system can be configured to receive a video frame with first RGB values at each pixel location and apply operation to determine second RGB values at each pixel location. The second RGB values can be associated with a transformed video frame which includes synthetic data. After the synthetic image is generated, the native video frame and/or the synthetic image can be sent to a persistent memory, such as a flash memory or a hard drive, for storage. In addition, the synthetic image and/or native video data can be sent to a frame buffer for output on a display or displays associated with an output interface. For example, the display can be the display on a mobile device or a view finder on a camera.

In general, the video transformations used to generate synthetic images can be applied to the native video data at its native resolution or at a different resolution. For example, the native video data can be a 512 by 512 array with RGB values represented by 24 bits and at frame rate of 24 fps. In some embodiments, the video transformation can involve operating on the video data in its native resolution and outputting the transformed video data at the native frame rate at its native resolution.

In other embodiments, to speed up the process, the video transformations may involve operating on video data and outputting transformed video data at resolutions, color depths and/or frame rates different than the native resolutions. For example, the native video data can be at a first video frame rate, such as 24 fps. But the video transformations can be performed on every other frame and synthetic images can be output at a frame rate of 12 fps. Alternatively, the transformed video data can be interpolated from the 12-fps rate to 24 fps rate by interpolating between two of the transformed video frames.

In another example, prior to performing the video transformations, the resolution of the native video data can be reduced. For example, when the native resolution is 512 by 512 pixels, it can be interpolated to a 256 by 256-pixel array using a technique such as pixel averaging and then the transformation can be applied to the 256 by 256 array. The transformed video data can output and/or stored at the lower 256 by 256 resolution. Alternatively, the transformed video data, such as with a 256 by 256 resolution, can be interpolated to a higher resolution, such as its native resolution of 512 by 512, prior to output to the display and/or storage. The coarsening of the native video data prior to applying the video transformation can be used alone or in conjunction with a coarser frame rate.

As mentioned above, the native video data can also have a color depth. The color depth can also be coarsened prior to applying the transformations to the video data. For example, the color depth might be reduced from 40 bits to 24 bits prior to applying the transformation.

As described above, native video data from a live video can be augmented with virtual data to create synthetic images and then output in real-time. In particular embodiments, real-time can be associated with a certain amount of latency, i.e., the time between when the native video data is captured and the time when the synthetic images including portions of the native video data and virtual data are output. In particular, the latency can be less than 100 milliseconds. In other embodiments, the latency can be less than 50 milliseconds. In other embodiments, the latency can be less than 30 milliseconds. In yet other embodiments, the latency can be less than 20 milliseconds. In yet other embodiments, the latency can be less than 10 milliseconds.

The interface 511 may include separate input and output interfaces or may be a unified interface supporting both operations. Examples of input and output interfaces can include displays, audio devices, cameras, touch screens, buttons, and microphones. When acting under the control of appropriate software or firmware, the processor 501 is responsible for such tasks such as optimization. Various specially configured devices can also be used in place of a processor 501 or in addition to processor 501, such as graphical processor units (GPUs). The complete implementation can also be done in custom hardware. The interface 511 is typically configured to send and receive data packets or data segments over a network via one or more communication interfaces, such as wireless or wired communication interfaces. Particular examples of interfaces the device supports include Ethernet interfaces, frame relay interfaces, cable interfaces, DSL interfaces, token ring interfaces, and the like.

In addition, various very high-speed interfaces may be provided such as fast Ethernet interfaces, Gigabit Ethernet interfaces, ATM interfaces, HSSI interfaces, POS interfaces, FDDI interfaces and the like. Generally, these interfaces may include ports appropriate for communication with the appropriate media. In some cases, they may also include an independent processor and, in some instances, volatile RAM. The independent processors may control such communications intensive tasks as packet switching, media control and management.

According to various embodiments, the system 500 uses memory 503 to store data and program instructions and maintained a local side cache. The program instructions may control the operation of an operating system and/or one or more applications, for example. The memory or memories may also be configured to store received metadata and batch requested metadata. The memory 503 may include one or more non-transitory computer readable media having instructions stored thereon for performing any of the methods disclosed herein such as the method 100 of FIG. 1.

The system 500 of FIG. 5 can be integrated into a single device with a common housing. For example, system 500 can include a camera system, processing system, frame buffer, persistent memory, output interface, input interface and communication interface. In various embodiments, the single device can be a mobile device like a smart phone, an augmented reality and wearable device like Google Glass™ or a virtual reality head set that includes multiple cameras, like a Microsoft Hololens™. In other embodiments, the system 500 can be partially integrated. For example, the camera system can be a remote camera system. As another example, the display can be separated from the rest of the components like on a desktop PC. In some implementations, the system 500 of FIG. 5 may be distributed across devices such as server systems, database systems, camera systems, etc.

1. A method comprising:
maintaining a computing system configured to process a plurality of intermediate outputs from machine learning models to generate combined outputs, the intermediate outputs having corresponding confidence metrics;
automatically determining a combined confidence metric that reflects a probability that the combined outputs are accurate;
automatically determining, using the combined confidence metrics, suitability of the combined outputs as inputs for a further model; and
causing, based on the determined suitability of the combined outputs, the suitable combined outputs to be used as inputs for the further model.

2. The method of claim 1 wherein automatically determining suitability of the combined outputs as inputs for the further model comprises using a weighted ranking system, wherein weights are assigned to the combined outputs based on specific requirements of the further model.

3. The method of claim 1, wherein automatically determining suitability of the combined outputs as inputs for the further model comprises dynamically adjusting a threshold for suitability of the combined outputs based on substantially real-time performance metrics of the further model.

4. The method of claim 3, wherein dynamically adjusting a threshold for suitability of the combined output based on substantially real-time performance metrics of the further model comprises applying feedback loops where the performance of the further model on inputs from the suitable combined outputs is monitored, and ranking criteria are adjusted to optimize this performance.

5. The method of claim 1, wherein the suitable combined outputs are one set of a plurality of inputs for the further model, the sets of inputs each being ranked based on different criteria.

6. The method of claim 1, wherein automatically determining suitability of the combined outputs as inputs for the further model is further based on further data in addition to the combined confidence metrics.

7. The method of claim 6 wherein the further data includes an external metric measured based on data sources used, machine learning models employed, and/or feature sets analyzed.

8. A computing system implemented using a server system, the computing system configured to cause:
maintaining a computing system configured to process a plurality of intermediate outputs from machine learning models to generate combined outputs, the intermediate outputs having corresponding confidence metrics;
automatically determining a combined confidence metric that reflects a probability that the combined outputs are accurate;
automatically determining, using the combined confidence metrics, suitability of the combined outputs as inputs for a further model; and
causing, based on the determined suitability of the combined outputs, the suitable combined outputs to be used as inputs for the further model.

9. The computing system of claim 8, wherein automatically determining suitability of the combined outputs as inputs for the further model comprises using a weighted ranking system, wherein weights are assigned to the combined outputs based on specific requirements of the further model.

10. The computing system of claim 8, wherein automatically determining suitability of the combined outputs as inputs for the further model comprises dynamically adjusting a threshold for suitability of the combined outputs based on substantially real-time performance metrics of the further model.

11. The computing system of claim 10, wherein dynamically adjusting a threshold for suitability of the combined output based on substantially real-time performance metrics of the further model comprises applying feedback loops where the performance of the further model on inputs from the suitable combined outputs is monitored, and ranking criteria are adjusted to optimize this performance.

12. The computing system of claim 8, wherein the suitable combined outputs are one set of a plurality of inputs for the further model, the sets of inputs each being ranked based on different criteria.

13. The computing system of claim 8, wherein automatically determining suitability of the combined outputs as inputs for the further model is further based on further data in addition to the combined confidence metrics.

14. The computing system of claim 13, wherein the further data includes an external metric measured based on data sources used, machine learning models employed, and/or feature sets analyzed.

15. One or more non-transitory computer readable media having instructions stored thereon for performing a method, the method comprising:
maintaining a computing system configured to process a plurality of intermediate outputs from machine learning models to generate combined outputs, the intermediate outputs having corresponding confidence metrics;
automatically determining a combined confidence metric that reflects a probability that the combined outputs are accurate;
automatically determining, using the combined confidence metrics, suitability of the combined outputs as inputs for a further model; and
causing, based on the determined suitability of the combined outputs, the suitable combined outputs to be used as inputs for the further model.

16. The one or more non-transitory computer readable media of claim 15, wherein automatically determining suitability of the combined outputs as inputs for the further model comprises using a weighted ranking system, wherein weights are assigned to the combined outputs based on specific requirements of the further model.

17. The one or more non-transitory computer readable media of claim 15, wherein automatically determining suitability of the combined outputs as inputs for the further model comprises dynamically adjusting a threshold for suitability of the combined outputs based on substantially real-time performance metrics of the further model.

18. The one or more non-transitory computer readable media of claim 17, wherein dynamically adjusting a threshold for suitability of the combined output based on substantially real-time performance metrics of the further model comprises applying feedback loops where the performance of the further model on inputs from the suitable combined outputs is monitored, and ranking criteria are adjusted to optimize this performance.

19. The one or more non-transitory computer readable media of claim 15, wherein the suitable combined outputs are one set of a plurality of inputs for the further model, the sets of inputs each being ranked based on different criteria.

20. The one or more non-transitory computer readable media of claim 15, wherein automatically determining suitability of the combined outputs as inputs for the further model is further based on further data in addition to the combined confidence metrics.
